(19) United States
(12) Patent Application Publication
(10) Pub. No.: US 2015/0136218 A1
(43) Pub. Date: May 21, 2015

(54) SOLAR CELL AND METHOD OF FABRICATING THE SAME

(71) Applicant: LG INNOTEK CO., LTD., Seoul (KR)

(72) Inventor: Jin Ho Gwon, Seoul (KR)

(73) Assignee: LG INNOTEK CO., LTD., Seoul (KR)

(21) Appl. No.: 14/401,153

(22) PCT Filed: Jun. 26, 2013
(86) PCT No.: PCT/KR2013/005668

§ 371 Date: Nov. 14, 2014

(30) Foreign Application Priority Data
Jun. 28, 2012 (KR) 10-2012-0070356

(51) Int. Cl. H01L 31/0352; H01L 31/0224; H01L 31/0216

(52) U.S. Cl. CPC H01L 31/035281; H01L 31/02167; H01L 31/022433
USPC 136/256; 136/252; 136/261

(57) ABSTRACT

A solar cell and a method of fabricating the same are provided. The solar cell includes a substrate, a back electrode layer on the substrate, a light absorbing layer on the back electrode layer, and a buffer layer on the light absorbing layer. The back electrode layer, the light absorbing layer, and the buffer layer are formed therein with a first through hole formed through the back electrode layer, the light absorbing layer, and the buffer layer, and an insulating member is deposited in the first through hole.

### TECHNICAL FIELD

The embodiment relates to a solar cell and a method of fabricating the same.

### BACKGROUND ART

A method of fabricating a solar cell for solar light power generation is as follows. First, after preparing a substrate, a back electrode layer is formed on the substrate, and patterned by a laser to form a plurality of back electrodes.

Thereafter, a light absorbing layer, a buffer layer, and a high resistance buffer layer are sequentially formed on the back electrodes. Various schemes, such as a scheme of forming a Cu(In,Ga)Se2 (CIGS) based-light absorbing layer by simultaneously or separately evaporating copper (Cu), indium (In), gallium (Ga), and selenium (Se) and a scheme of performing a selenization process after a metallic precursor film has been formed, have been extensively used in order to form the light absorbing layer. The energy bandgap of the light absorbing layer is in the range of about 1 eV to 1.8 eV.

Then, the buffer layer including cadmium sulfide (CdS) is formed on the light absorbing layer through a sputtering process. The energy bandgap of the buffer layer may be in the range of about 2.2 eV to 2.4 eV. After that, the high resistance buffer layer including zinc oxide (ZnO) is formed on the buffer layer through the sputtering process. The energy bandgap of the high resistance buffer layer is in the range of about 3.1 eV to about 3.3 eV.

Thereafter, holes patterns may be formed in the light absorbing layer, the buffer layer, and the high resistance buffer layer.

Then, a transparent conductive material is laminated on the high resistance buffer layer, and the hole patterns are filled with the transparent conductive material. Accordingly, a transparent electrode layer is formed on the high resistance buffer layer, and connection wires are formed inside the holes patterns. A material constituting the transparent electrode layer and the connection wires may include aluminum doped zinc oxide (AZO). The energy bandgap of the transparent electrode layer may be in the range of about 3.1 eV to 3.3 eV.

Then, the hole pattern is formed in the transparent electrode layer, so that a plurality of solar cells may be formed. The transparent electrodes and the high resistance buffers correspond to the cells, respectively. The transparent electrodes and the high resistance buffers may be provided in the form of a stripe or a matrix.

The transparent electrodes and the back electrodes are misaligned from each other and electrically connected with each other by the connection wires. Accordingly, the solar cells may be electrically connected to each other in series.

As described above, in order to convert the solar light into electrical energy, various solar cell apparatuses have been fabricated and used. One of the solar cell apparatuses is disclosed in Korean Unexamined Patent Publication No. 10-2008-0088744.

Meanwhile, according to the related art, after dividing the back electrode layer into a plurality of back electrodes by patterning the back electrode layer, the light absorbing layer, the buffer layer, and the front electrode layer are laminated on the back electrode layer to fabricate the solar cell.

However, since a deposition process of the light absorbing layer is performed at the high temperature of 500° C. or more, a support substrate may be bent due to the deposition process of the light absorbing layer. Accordingly, the bending phenomenon of the support substrate may exert an influence on even the back electrode layer provided on the support substrate, and the patterns formed in the back electrode layer may be bent. The bending phenomenon increases a dead zone of a solar cell, in which power is not generated, so that the whole efficiency of the solar cell may be reduced.

Accordingly, the necessity for a solar cell capable of preventing the support substrate from being bent and a method of fabricating the same is raised.

### DISCLOSURE OF INVENTION

### Technical Problem

The embodiment provides a solar cell capable of improving photoelectric conversion efficiency and a method of fabricating the same.

### Solution to Problem

According to the embodiment, there is provided a solar cell including a substrate, a back electrode layer on the substrate, a light absorbing layer on the back electrode layer, and a buffer layer on the light absorbing layer. The back electrode layer, the light absorbing layer, and the buffer layer are formed therein with a first through hole formed through the back electrode layer, the light absorbing layer, and the buffer layer, and an insulating member is deposited in the first through hole.

According to the embodiment, there is provided a method of fabricating the solar cell. The method includes forming a back electrode layer on a substrate, forming a light absorbing layer on the back electrode layer, forming a buffer layer on the light absorbing layer, forming a first through hole through the back electrode layer, the light absorbing layer, and the buffer layer, and depositing an insulating member in the first through hole.

### Advantageous Effects of Invention

As described above, according to the solar cell and the method of fabricating the same of the embodiment, the insulating member is deposited in the first through holes formed through the back electrode layer, the light absorbing layer, and the buffer layer, and a plurality of back electrodes are defined in the back electrode layer by the first through holes and the insulating member.

In other words, according to the solar cell and the method of fabricating the same of the embodiment, after depositing the light absorbing layer and the buffer layer on the back electrode layer, the through holes are formed through the back electrode layer, the light absorbing layer, and the buffer layer, and the insulating member is deposited in the through holes to divide the back electrode layer into a plurality of back electrodes.

Therefore, since a process to divide the back electrode layer into a plurality of back electrodes is performed after the depositing process of the light absorbing layer, the support substrate can be prevented from being bent due to the high-temperature process of the light absorbing layer.

Accordingly, the dead zone can be reduced, and the whole efficiency of the solar cell can be increased.

### BRIEF DESCRIPTION OF DRAWINGS

FIG. 1 is a plan view showing a solar cell according to the embodiment.

FIG. 2 is a sectional view showing the solar cell according to the embodiment.

FIGS. 3 to 9 are sectional views showing a method of fabricating a solar cell according to the embodiment.

### MODE FOR THE INVENTION

In the following description of the embodiments, it will be understood that, when a layer (film), a region, a pattern or a structure is referred to as being “on” or “under” another substrate, layer (film), region, pad or pattern, it can be “directly” or “indirectly” on the other substrate, layer (film), region, pad, or pattern, or one or more intervening layers may also be present. Such a position of each layer will be described with reference to the drawings.

The thickness and size of each layer (film), region, pattern or structure shown in the drawings may be modified for the purpose of convenience or clarity. In addition, the size of each layer (film), region, pattern or structure does not utterly reflect an actual size.

Hereinafter, the embodiment will be described in detail with reference to accompanying drawings.

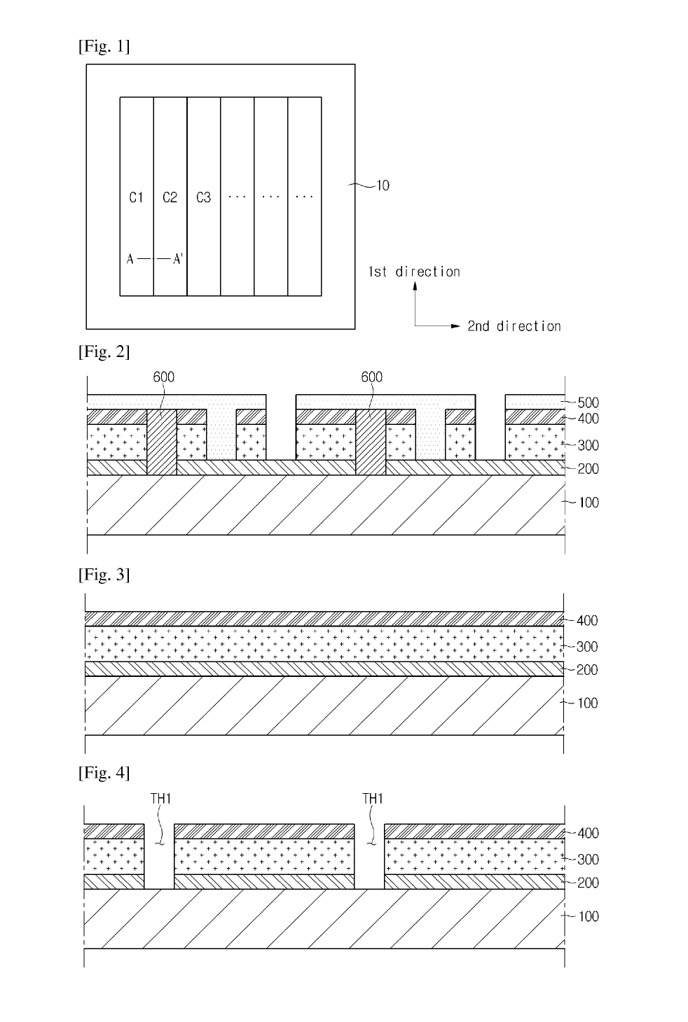

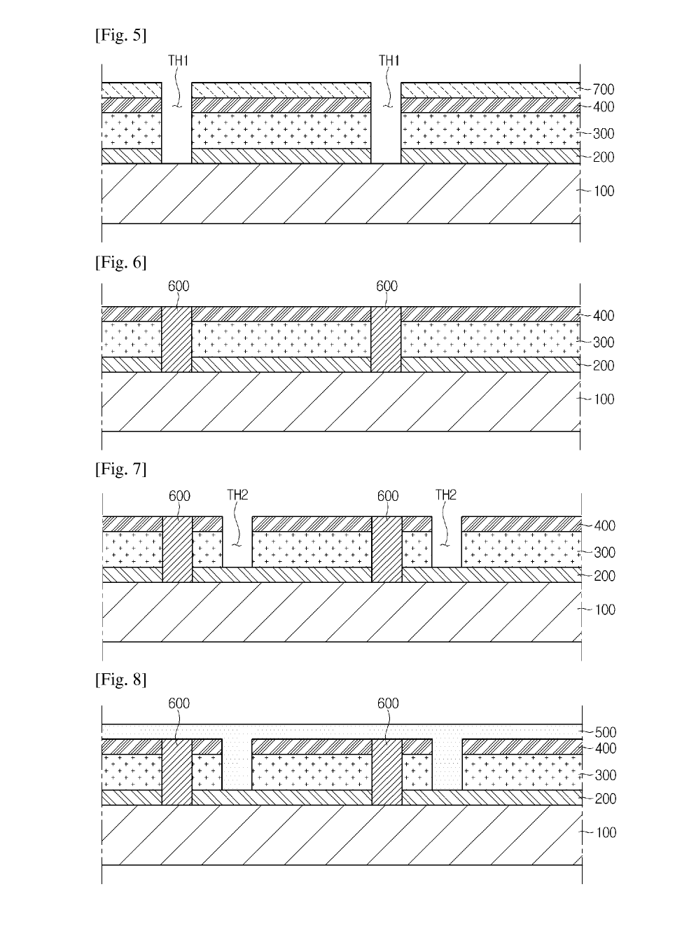

Hereinafter, the solar cell according to the embodiment will be described in detail with reference to FIGS. 1 and 2. FIG. 1 is a plan view showing the solar cell according to the embodiment, and FIG. 2 is a sectional view showing the solar cell according to the embodiment.

Referring to FIGS. 1 and 2, the solar cell according to the embodiment includes a support substrate 100, a back electrode layer 200, a light absorbing layer 300, a buffer layer 400, a front electrode layer 500, and a plurality of insulating members 600.

The support substrate 100 has a plate shape and supports the back electrode layer 200, the light absorbing layer 300, the buffer layer 400, the front electrode layer 500, and the insulating members 600.

The support substrate 100 may include an insulator. The support substrate 100 may include a glass substrate, a plastic substrate, or a metallic substrate. In more detail, the support substrate 100 may include a soda lime glass substrate. Alternatively, the support substrate 100 may include a ceramic substrate including alumina, stainless steel, or polymer having a flexible property. The support substrate 100 may be transparent. The support substrate 100 may be rigid or flexible.

The back electrode layer 200 is provided on the support substrate 100. The back electrode layer 200 is a conductive layer, the back electrode layer 200 may include one of molybdenum (Mo), gold (Au), aluminum (Al), chrome (Cr), tungsten (W), and copper (Cu). Among then, especially, Mo makes the lower difference in the thermal expansion coefficient from the support substrate 100 when comparing with the other elements, so that the Mo represents a superior adhesive property, thereby preventing the above de-lamination phenomenon.

In addition, the back electrode layer 200 may include at least two layers. In this case, the layers may include the same metal or different metals.

The light absorbing layer 300 is provided on the back electrode layer 200.

The light absorbing layer 300 may include a group I-III-VI-based compound. For example, the light absorbing layer 300 may have a Cu(In,Ga)Se2 (CIGS) crystal structure, a Cu(In)Se2 crystal structure, or a Cu(Ga)Se2 crystal structure.

The light absorbing layer 300 may have an energy bandgap in the range of 1 eV to 1.8 eV.

The buffer layer 400 is provided on the light absorbing layer 300. The buffer layer 400 directly makes contact with the light absorbing layer 300. The buffer layer 400 includes CdS, ZnS, InXSY or InXSeYZn(O, OH). The buffer layer 400 may have the thickness in the range of about 50 nm to about 150 nm, and may have the energy bandgap in the range of about 2.2 eV to 2.4 eV.

A high resistance buffer layer may be further provided on the buffer layer 400. The high resistance buffer layer includes zinc oxide (i-ZnO) which is not doped with impurities. The energy bandgap of the high resistance buffer layer may be in the range of about 3.1 eV to about 3.3 eV. Alternatively, the high resistance buffer layer may be omitted.

The buffer layer 400 may be formed therein with first through holes TH1. In detail, the first through holes TH1 may be formed through the buffer layer 400, the light absorbing layer 300, and the back electrode layer 200.

Each first through hole TH1 may have the width in the range of about 80 μm to about 200 μm.

The insulating member 600 may be positioned inside each first through hole TH1. In detail, the insulating member 600 may be deposited inside the first through hole TH1.

The insulating member 600 may include silicon. In detail, the insulating member 600 may include silicon, oxide including silicon, or nitride include silicon. For example, the insulating member 600 may include SiOx (X is in 0≦X≦2), or SixNy (X is in 0<X≦3 and Y is in 0≦Y≦4). In other words, the insulating member 600 may include at least one of silicon, oxide including silicon, and nitride including silicon.

The insulating member 600 may directly make contact with lateral sides of the back electrode layer 200, the light absorbing layer 300, and the buffer layer 400 exposed through the first through holes TH1.

Accordingly, the back electrode layer 200 is divided into a plurality of back electrodes by the first through holes TH1. In other words, the back electrodes are defined by the first through holes TH1.

The back electrodes are spaced apart from each other by the first through holes TH1. The back electrodes are arranged in the shape of a stripe.

Alternatively, the back electrodes may be arranged in the shape of a matrix. In this case, when viewed in a plan view, the first through holes TH1 may be provided in the shape of a lattice.

In addition, the buffer layer 400 may be formed therein with second through holes TH2. The second through holes TH2 are open regions to expose the top surface of the support substrate 100 and the top surface of the back electrode layer 200. When viewed in a plan view, the second through holes TH2 may have the shape extending in one direction. Each of the second through holes TH2 may have the width in the range of about 80 μm to about 200 μm, but the embodiment is not limited thereto.

A plurality of buffer layers are defined in the buffer layer 400 by the second through holes TH2. In other words, the buffer layer 400 is divided into the buffer layers by the second through holes TH2.

The front electrode layer 500 is provided on the buffer layer 400 and/or the high resistance buffer layer. The front electrode layer 500 is transparent and includes a conductive layer. In addition, the front electrode layer 500 has resistance higher than that of the back electrode layer 500.

The front electrode layer 500 includes oxide. For example, a material constituting the front electrode layer 500 may include Al doped zinc oxide (AZO), indium zinc oxide (IZO), or indium tin oxide (ITO).

The front electrode layer 500 may have the characteristics of an N type semiconductor. In this case, the front electrode layer 500 forms an N type semiconductor together with the buffer layer 400 to make a PN junction with the light absorbing layer 300 serving as a P type semiconductor layer. The front electrode layer 500 may have the thickness of about 100 nm or about 500 nm.

The front electrode layer 500 may have the thickness in the range of about 500 nm to about 1.5 μm. In addition, if the front electrode layer 500 includes Al doped ZnO, the Al may be doped with the content of about 2.5 wt % to about 3.5 wt %.

The buffer layer 400 and the front electrode layer 500 are formed therein with third through holes TH3. The third through holes TH3 may be formed through a portion or an entire portion of the buffer layer 400, the high resistance buffer layer, and the front electrode layer 500. In other words, the third through holes TH3 may expose the top surface of the back electrode layer 200.

The third through holes TH3 are formed adjacent to the second through holes TH2. In detail, the third through holes TH3 are provided beside the second through holes TH2. In other words, when viewed in a plan view, the third through holes TH3 are provided in parallel to the second through holes TH2. The third through holes TH3 may have the shape extending in the first direction.

The third through holes TH3 are formed through the front electrode layer 500. In detail, the third through holes TH3 may be formed through the light absorbing layer 300, the buffer layer 400, and/or a portion or an entire portion of the high resistance buffer layer.

The front electrode layer 500 is divided into a plurality of front electrodes by the third through holes TH3. In other words, the front electrodes are defined by the third through holes TH3.

Each front electrode has a shape corresponding to the shape of each back electrode. In other words, the front electrodes are arranged in the shape of a stripe. Alternatively, the front electrodes may be arranged in the shape of a matrix.

In addition, a plurality of solar cells C1, C2, . . . , and Cn are defined by the third through holes TH3. In detail, the solar cells C1, C2, . . . , and Cn are defined by the second and third through holes TH2 and TH3. In other words, the solar cell apparatus according to the embodiment is divided into the solar cells C1, C2, . . . , and Cn by the second and third through holes TH2 and TH3. In addition, the solar cells C1, C2, . . . , and Cn are connected to each other in a second direction crossing the first direction. In other words, current may flow through the solar cells C1, C2, . . . , and Cn in the second direction.

In other words, a solar cell panel 10 includes the support substrate 100 and the solar cells C1, C2, . . . , and Cn. The solar cells C1, C2, . . . , and Cn are provided on the support substrate 100, and spaced apart from each other. The solar cells C1, C2, . . . , and Cn are connected to each other in series by connection parts.

The connection parts are provided inside the second through holes TH2. The connection parts extend downward from the front electrode layer 500, so that the connection parts are connected to the back electrode layer 200. For example, the connection parts extend from the front electrode of the first cell C1 so that the connection parts are connected to the back electrode of the second cell C2.

Therefore, the connection parts connect adjacent cells to each other. In more detail, the connection parts connect front and back electrodes, which constitute adjacent cells, to each other.

The connection parts are integrally formed with the front electrode layer 500. In other words, a material constituting the connection parts is the same as a material constituting the front electrode layer 500.

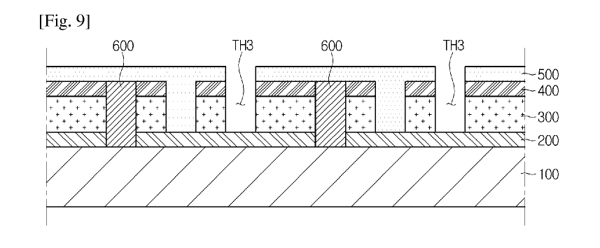

Hereinafter, a method of fabricating the solar cell according to the embodiment will be described with reference to FIGS. 3 to 9. FIGS. 3 to 9 are sectional views to explain the method of fabricating the solar cell according to the embodiment.

First, referring to FIG. 3, the back electrode layer 200, the light absorbing layer 300, and the buffer layer 400 are formed on the support substrate 100. In more detail, the back electrode layer 200 is formed on the support substrate 100, the light absorbing layer 300 is formed on the back electrode layer 200, and the buffer layer 400 is formed on the light absorbing layer 300.

The back electrode layer 200 may be formed through a physical vapor deposition (PVD) or a plating scheme.

In addition, the light absorbing layer 300 may be formed through a sputtering process or an evaporation scheme. For example, in order to form the light absorbing layer 300, a scheme of forming a Cu(In,Ga)Se2 (CIGS) based-light absorbing layer 300 by simultaneously or separately evaporating Cu, In, Ga, and Se and a scheme of performing a selenization process after forming a metallic precursor film have been extensively performed.

Regarding the details of the selenization process after forming the metallic precursor layer, the metallic precursor layer is formed on the back electrode 200 through a sputtering process employing a Cu target, an In target, or a Ga target.

Thereafter, the metallic precursor layer is subject to the selenization process so that the Cu(In,Ga)Se2 (CIGS) based-light absorbing layer 300 is formed.

In addition, the sputtering process employing the Cu target, the In target, and the Ga target and the selenization process may be simultaneously performed.

Alternatively, a CIS or a CIG light absorbing layer 300 may be formed through a sputtering process employing only Cu and In targets or only Cu and Ga targets and the selenization process.

In addition, the buffer layer 400 may be formed through various schemes sufficient to form a buffer layer of the solar cell in the related art.

For example, the buffer layer 400 may be formed through one selected from the group consisting of sputtering, evaporation, chemical vapor deposition (CVD), metal organic chemical vapor deposition (MOCVD), close-spaced sublimation (CSS), spray pyrolysis, chemical spraying, screen printing, vacuum-free liquid-phase film deposition, chemical-bath deposition (CBD), vapor transport deposition (VTD), atomic layer deposition (ALD), and electro-deposition schemes. In detail, the buffer layer 400 may be fabricated through a CBD scheme, an atomic layer deposition (ALD) scheme, or an MOCVD scheme.

Thereafter, referring to FIG. 4, the first through holes TH 1 are formed by removing the buffer layer 400, the light absorbing layer 300, and a portion of the back electrode layer 200.

The first through holes TH1 may be formed by using a mechanical device such as a tip or a laser device. For example, the first through holes TH1 may be formed by simultaneously perforating the buffer layer 400, the light absorbing layer 300, and the back electrode layer 200 by a laser having a predetermined wavelength. In addition, each first through hole TH1 may be formed by forming a hole through the buffer layer 400 and the light absorbing layer 300 by using a mechanical device such as a tip and perforating the top surface of the back electrode layer exposed through the hole by a laser device.

Thereafter, referring to FIGS. 5 and 6, the insulating member 600 may be deposited inside the first through holes TH1.

The insulating member 600 may include at least one of silicon, silicon-based oxide, and silicon-based nitride.

The insulating member 600 may be deposited inside the first through holes TH1 through the sputtering scheme or the CVD scheme after depositing a mask on the buffer layer. Accordingly, the insulating member 600 may directly make contact with lateral sides of the back electrode layer 200, the light absorbing layer 300, and the buffer layer 400 exposed through the first through holes TH1.

Therefore, the back electrode layer 200 is divided into a plurality of back electrodes by the first through holes TH1 and the insulating member 600. In other words, the back electrodes are defined by the first through holes TH1.

Thereafter, referring to FIG. 7, the second through holes TH2 are formed by partially removing the light absorbing layer 300 and the buffer layer 400.

The second through holes TH2 may be formed by the mechanical device such as a tip or a laser device.

For example, the light absorbing layer 300 and the buffer layer 400 may be patterned by a tip having a width of about 40 μm to about 180 μm. In addition, the second through holes TH2 may be formed by a laser having a wavelength of about 200 nm to about 600 nm.

In this case, the second through holes TH2 may have the width of about 100 μm to about 200 μm. In addition, the second through holes TH2 exposes a portion of the top surface of the back electrode layer 200.

Thereafter, referring to FIG. 8, the front electrode layer may be formed on the buffer layer 400. For example, the front electrode layer 800 may be deposited through an RF sputtering scheme using a ZnO target, a reactive sputtering scheme using a Zn target, or an MOCVD scheme.

Thereafter, referring to FIG. 9, the third through holes TH3 are formed by partially removing the light absorbing layer 300, the buffer layer 400, and the front electrode layer 500. Therefore, the front electrode layer 500 is patterned to define a plurality of front electrodes and first to third cells C1 to C3. Each third through holes TH3 have the width of about 80 μm to about 200 μm.

According to the solar cell and the method of fabricating the same of the embodiment, the insulating member is deposited in the first through holes formed through the back electrode layer, the light absorbing layer, and the buffer layer, and a plurality of back electrodes are defined in the back electrode layer by the first through holes and the insulating member.

According to the related art, after dividing the back electrode layer into a plurality of back electrodes by patterning the back electrode layer, the light absorbing layer, the buffer layer, and the front electrode layer are deposited on the back electrode layer to fabricate the solar cell.

However, since a deposition process of the light absorbing layer is performed at the high temperature of 500° C. or more, a support substrate may be bent due to the deposition process of the light absorbing layer. Accordingly, the bending phenomenon of the support substrate may exert an influence on even the back electrode layer provided on the support substrate, and the patterns formed in the back electrode layer may be bent. The bending phenomenon increases a dead zone of a solar cell, in which power is not generated, so that the whole efficiency of the solar cell may be reduced.

Therefore, according to the solar cell and the method of fabricating the same of the embodiment, after depositing the light absorbing layer and the buffer layer on the back electrode layer, through holes are formed through the back electrode layer, the light absorbing layer, and the buffer layer, and the insulating member is deposited in the through holes to divide the back electrode layer into a plurality of back electrodes.

Therefore, since a process to divide the back electrode layer into a plurality of back electrodes is performed after the depositing process of the light absorbing layer, the support substrate can be prevented from being bent due to the high-temperature process of the light absorbing layer.

Accordingly, the dead zone can be reduced, and the whole efficiency of the solar cell can be increased.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a substrate;
a back electrode layer on the substrate;
a light absorbing layer on the back electrode layer; and
a buffer layer on the light absorbing layer,
wherein a first through hole is formed through the back electrode layer, the light absorbing layer, and the buffer layer and an insulating member is deposited in the first through hole.

2. The solar cell of claim 1, wherein the insulating member comprises at least one of silicon, oxide comprising silicon, and nitride comprising silicon.

3. The solar cell of claim 2, wherein the insulating member comprises at least one of SiOx, in which X is in 0≦X≦2, or SixNy in which X is in 0<X≦3 and Y is in 0≦Y≦4.

4. The solar cell of claim 1, wherein the insulating member directly makes contact with lateral sides of the back electrode layer, the light absorbing layer, and the buffer layer exposed through the first through hole.

5. The solar cell of claim 1, further comprising a second through hole formed through the light absorbing layer and the buffer layer.

6. The solar cell of claim 4, further comprising a front electrode layer on the buffer layer.

7. (canceled)

8. (canceled)

9. (canceled)

10. (canceled)

11. (canceled)

12. The solar cell of claim 1, wherein the first through hole has the width in the range of 80 μm to 200 μm.

13. The solar cell of claim 1, wherein the back electrode layer is divided into a plurality of back electrodes by the first through holes.

14. The solar cell of claim 13, wherein the back electrodes are spaced apart from each other by the first through holes.

15. The solar cell of claim 14, wherein the back electrodes are arranged in the shape of a stripe or matrix.

16. The solar cell of claim 5, wherein a plurality of buffer layers are defined in the buffer layer by the second through holes.
